(19) United States
(12) Patent Application Publication
(10) Pub. No.: US 2024/0365520 A1
(43) Pub. Date: Oct. 31, 2024

(54) THERMAL DEVICE WITH GRADIENT PIN FINS FOR ELECTRONICS

(71) Applicant: Atieva, Inc., Newark, CA (US)

(72) Inventors: Samaneh Sadri, Redwood City, CA (US); Duncan Ryan Marks, Palo Alto, CA (US); Alexander Gates Moore Tsang, Oakland, CA (US)

(21) Appl. No.: 18/329,369

(22) Filed: Jun. 5, 2023

Related U.S. Application Data
(60) Provisional application No. 63/498,320, filed on Apr. 26, 2023.

(51) Int. Cl. H05K 7/20

(52) U.S. Cl. CPC H05K 7/20927

(57) ABSTRACT

A thermal device for electronics comprises: a baseplate configured for having the electronics mounted thereto; a manifold defining a cavity closed by the baseplate, the cavity having an inlet and an outlet for a fluid; and pin fins extending from a surface of the baseplate inside the cavity, the pin fins arranged in a pattern, wherein a spacing between adjacent ones of the pin fins has a gradient.

### CROSS-REFERENCE TO RELATED APPLICATION

This application claims benefit, under 35 U.S.C. § 119, of U.S. Provisional Patent Application No. 63/498,320, filed on Apr. 26, 2023, entitled “THERMAL DEVICE WITH GRADIENT PIN FINS FOR ELECTRONICS”, the disclosure of which is incorporated by reference herein in its entirety.

### TECHNICAL FIELD

This document relates to a thermal device with gradient pin fins for electronics.

### BACKGROUND

Electronic components or devices occur in many areas, such as in consumer electronics, electric vehicles, stationary storages for electric power, and other electrical systems. In electric vehicles, power electronics can be included in an inverter that converts direct current from a high-voltage battery pack into alternating current for powering a propulsion motor, or to feed energy recovered from the motor to the battery pack. Similarly, power electronics can be used in non-mobile energy storage systems, for example when serving as a power solution for a house or another building. Cooling can be provided to remove heat generated by the electronics during operation.

### SUMMARY

In an aspect, a thermal device for electronics comprises: a baseplate configured for having the electronics mounted thereto; a manifold defining a cavity closed by the baseplate, the cavity having an inlet and an outlet for a fluid; and pin fins extending from a surface of the baseplate inside the cavity, the pin fins arranged in a pattern, wherein a spacing between adjacent ones of the pin fins has a gradient.

Implementations can include any or all of the following features. The pin fins are arranged in at least first and second regions on the baseplate, and wherein the gradient is formed by a first spacing between the pin fins in the first region and a second spacing between the pin fins in the second region. The baseplate comprises multiple regions including at least the first and second regions and a third region, the multiple regions arranged in a row on the baseplate. The gradient comprises that the spacing strictly decreases along the row in a flow direction of the fluid through the thermal device. The pattern comprises a hexagonal pattern of the pin fins. The pattern comprises an offset pattern of the pin fins. The pattern comprises that the pin fins are arranged in columns that are perpendicular to a flow direction of the fluid through the thermal device. The pin fins have a common separation from each other along each of the columns. Adjacent ones of the columns are offset from each other perpendicular to the flow direction of the fluid. A first pin fins of the pin fins is located in a first column of the columns, wherein second and third pin fins of the pin fins are located in a second column of the columns, the second column adjacent to the first column, and wherein the spacing is defined as a distance between the first pin fin and the second and third pin fins. The electronics comprises electronics modules arranged in a row on the baseplate. The thermal device is configured so the fluid forms parallel flows that are perpendicular to the row, and wherein the pattern comprises that a respective gradient is formed for each of the parallel flows. Flow directions of the parallel flows are in a common direction across the row. The thermal device is configured so the fluid forms a serial flow. The thermal device is configured so the serial flow forms a serpentine shape that repeatedly crosses the row. The pattern comprises that the gradient extends along the serial flow. The thermal device is configured so the fluid enters the thermal device at a first electronics module of the electronics modules and continues in first and second directions that are opposite each other and continues past second and third electronics modules that are at respective sides of the first electronics module in the row. The gradient comprises a first gradient along the first direction and a second gradient along the second direction. The thermal device is configured for cooling the electronics, and wherein the fluid is a coolant. The thermal device is configured for heating the electronics. The gradient extends along a flow direction of the fluid.

### BRIEF DESCRIPTION OF DRAWINGS

FIG. 1 shows a cross section of an example of a thermal device with gradient pin fins for electronics.

FIG. 2 shows a plan view of the baseplate of the thermal device of FIG. 1.

FIG. 3 schematically shows an example of pin fins arranged in regions on a baseplate.

FIGS. 4-7 show examples of thermal devices where electronics modules are arranged in a row on a baseplate.

FIGS. 8A-8B show examples of pin fins with an elliptical cross section in a hexagonal pattern and an offset pattern.

FIGS. 9A-9B show examples of pin fins with a circular cross section in a hexagonal pattern and an offset pattern.

Like reference symbols in the various drawings indicate like elements.

### DETAILED DESCRIPTION

This document describes examples of systems and techniques for thermal interaction with electronics, including but not limited to cooling. Pin fins that extend from a baseplate inside a cavity of a thermal device can be positioned in a pattern where the spacing between pin fins in at least one direction has a gradient. The gradient can include any type of configuration/separation change that causes a change in pin fin density (e.g., pin fin count per section or pin fin volume per section). This can improve cooling efficiency including flow and temperature distribution.

Examples described herein refer to electronics. As used herein, electronics includes any component or system that uses an active device to amplify and/or rectify and thereby control the flow of electrons. An electronic component can include one or more transistors. A high-voltage inverter is an example of a power electronics component.

Examples described herein refer to a fluid used in a thermal device. Such a fluid can be, but is not limited to, a coolant. As used herein, coolant includes any fluid used to regulate temperature. The coolant can include water (optionally with one or more additives), to name just one example. Coolant that passes through a cooler as described herein can be circulated in a thermal system. For example, such a system can also include one or more features for releasing heat, such as by conduction, convection, and/or radiation.

Examples described herein use the term “couple” or a variation of it when describing that a first feature and a second feature are coupled to each other. As used herein, being coupled indicates that the features are in fluid communication with each other. For example, coolant can flow from the first feature to the second feature, and/or can flow from the second feature to the first feature.

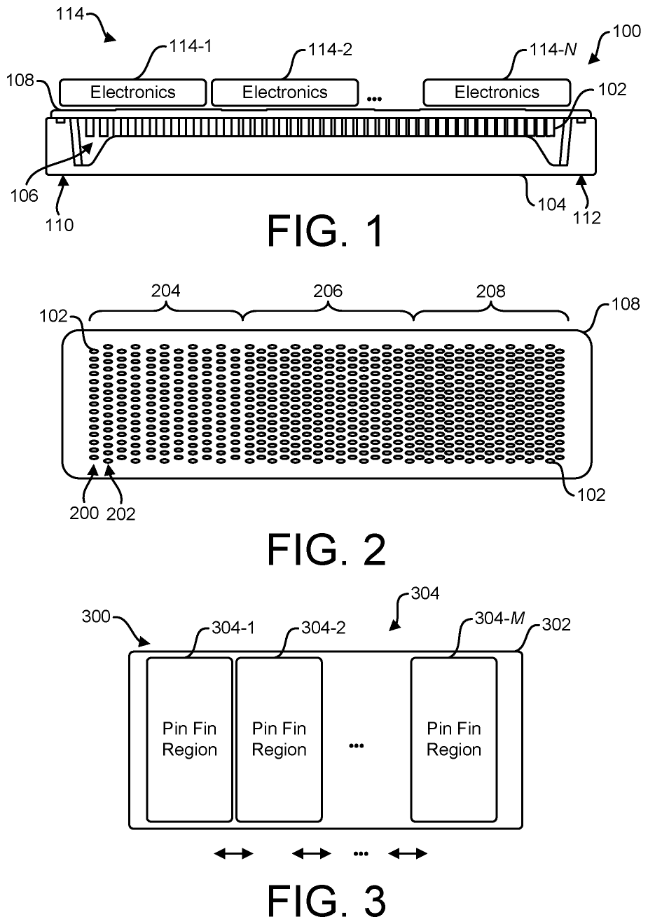

FIG. 1 shows a cross section of an example of a thermal device 100 with pin fins 102 for electronics. The thermal device 100 and/or the pin fins 102 can be used with one or more other examples described elsewhere herein. The thermal device 100 can be part of an installation that uses electronics (such installation including, but not limited to, a consumer electronics device, an electric vehicle, and/or a stationary storage for electric energy). For example, the thermal device 100 can cool the electronics. The thermal device 100 can be made using any of multiple materials, and any of multiple manufacturing techniques. In some implementations, a single-piece casting or molding process is used.

The thermal device 100 includes a manifold 104 defining a cavity 106 closed by a baseplate 108. In some implementations, the cavity 106 can be created other than by the baseplate 108. For example, the manifold 104 can be 3D-printed or investment cast as a single piece that includes the baseplate 108. The pin fins 102 extend from a surface of the baseplate 108 inside the cavity 106. The thermal device 100 has an inlet 110 where fluid can enter, and an outlet 112 where coolant can fluid. The manifold 104 forms one or more fluid paths between the inlet 110 and the outlet 112. The terms inlet and outlet, as used in any example described herein, are used for illustrative purposes only. The thermal device 100 is configured to have fluid flow through the cavity 106 and exchange thermal energy with the baseplate 108 through the pin fins 102. For example, the thermal device 100 can be a cooler for the electronics and the fluid can be a coolant.

Any number of electronics modules 114 can be thermally coupled to the thermal device 100. Electronics modules are schematically illustrated in the present disclosure. Here, the electronics modules 114 include electronics module 114-1, electronics module 114-2 through electronics module 114-N, where N=1, 2, 3, . . . . The electronics modules 114 can be mounted to the baseplate 108 and are in thermal contact with the baseplate 108. For example, when the thermal device 100 is a cooler the coolant can be used for removing heat from the electronics modules 114 and thereby controlling their respective temperatures.

FIG. 2 shows a plan view of the baseplate 108 of the thermal device of FIG. 1. During use, fluid will contact some or all of the fins 102 to allow transfer of thermal energy. The pin fins 102 are arranged in a pattern wherein a spacing between adjacent ones of the pin fins 102 has a gradient. Here, the pin fins 102 are arranged in multiple columns extending vertically in the present view. For example, a column 200 is positioned adjacent a column 202. The pin fins can have a common separation from each other within any or all of the columns 200-202. The pin fins in the column 202 can be offset relative to the pin fins of the column 200 perpendicular to the flow direction of the fluid. The pattern can involve the spacing between the rows 200-202 and other rows. For example, a region 204 of the pin fins 102 can have a first spacing, a region 206 of the pin fins 102 can have a second spacing, and a region 208 of the pin fins 102 can have a third spacing. The first, second and third spacings can be different from each other, thus forming one or more gradients. In some implementations, the baseplate 108 is configured for the fluid to flow from left to right in the plane of the present illustration. Some or all of the regions 204-208 can be arranged in a row with each other on the baseplate 108. The spacing between the pin fins 102 can strictly decrease along the row of the regions. That is, the first spacing can be the largest, the second spacing can be the second largest, and the third spacing can be the third largest. Other types of fins, placement of fins, and/or patterns of fins, can be used.

FIG. 3 schematically shows an example of pin fins 300 arranged in regions on a baseplate 302. The pin fins 300 and/or the baseplate 302 can be used with one or more other examples described elsewhere herein. The pin fins 300 can be arranged in any number of regions 304 on the baseplate 302. Here, the baseplate 302 includes a region 304-1, a region 304-2 through a region 304-M, where M=1, 2, 3, . . . . For example, some or all of the regions 304 can be arranged in a row with each other on the baseplate 302. The spacing between the pin fins 300 within any of the regions 304 can be constant or have a gradient. The spacing between the pin fins 300 in any of the regions 304 can be different from the spacing between the pin fins 300 in any other of the regions 304. As such, a gradient can be formed within any of the regions 304 and/or between two or more of the regions 304.

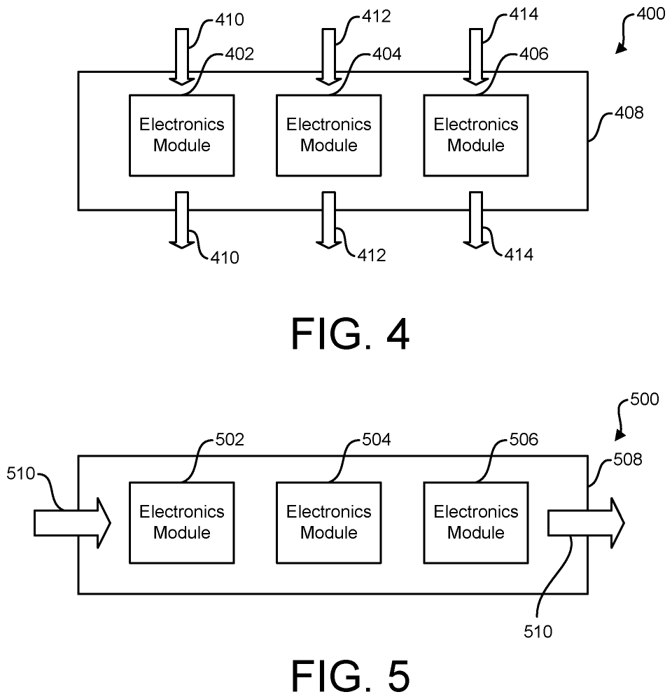

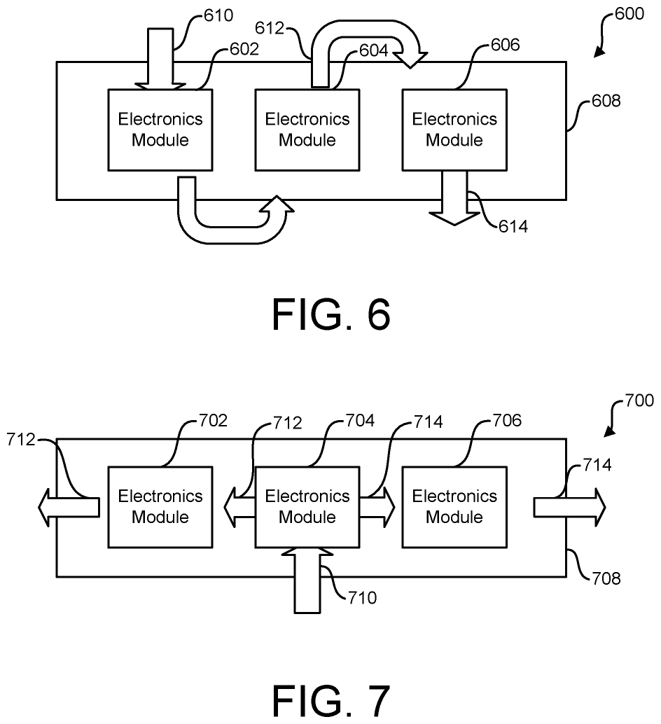

FIGS. 4-7 show examples of thermal devices 400, 500, 600 and 700 where electronics modules are arranged in a row on a baseplate. In the thermal device 400, electronics modules 402, 404 and 406 are arranged in a row on a baseplate 408. The thermal device 400 is configured so that the fluid forms parallel flows 410, 412 and 414 that are perpendicular to the row of the electronics modules 402-406. The parallel flows 410, 412 and 414 are here oriented in a common direction. The thermal device 400 can have pin fins extending from a surface of the baseplate 408 for some or all of the electronics modules 402-406. A spacing between adjacent ones of such pin fins can have a gradient. In some implementations, a gradient can be formed in the direction of flow for at least one of the parallel flows 410-414. For example, each of the parallel flows 410-414 can have a respective gradient in the spacing of the pin fins for the corresponding fluid flow. In other implementations, the gradient can also or instead be formed in a direction other than the direction of flow.

In the thermal device 500, electronics modules 502, 504 and 506 are arranged in a row on a baseplate 508. The thermal device 500 is configured so that the fluid forms a serial flow 510 along the row of the electronics modules 502-506. The thermal device 500 can have pin fins extending from a surface of the baseplate 508 for some or all of the electronics modules 502-506. A spacing between adjacent ones of such pin fins can have a gradient. In some implementations, a gradient can be formed in the direction of flow of the serial flow 510. As such, the gradient can extend along the serial flow 510.

In the thermal device 600, electronics modules 602, 604 and 606 are arranged in a row on a baseplate 608. The thermal device 600 is configured so that the fluid forms serial flows 610, 612 and 614 that are perpendicular to the row of the electronics modules 602-606. The thermal device 600 is configured so the fluid forms a serpentine shape that repeatedly crosses the row. For example, the flow direction of the serial flow 612 has an opposite direction to the flow direction of the serial flows 610 and 614. Other approaches can be used. The thermal device 600 can have pin fins extending from a surface of the baseplate 608 for some or all of the electronics modules 602-606. A spacing between adjacent ones of such pin fins can have a gradient. In some implementations, a gradient can be formed in the direction of flow for at least one of the parallel flows 610-614. For example, each of the parallel flows 610-614 can have a respective gradient in the spacing of the pin fins for the corresponding fluid flow. In other implementations, the gradient can also or instead be formed in a direction other than the direction of flow.

In the thermal device 700, electronics modules 702, 704 and 706 are arranged in a row on a baseplate 708. The thermal device 700 is configured so that the fluid forms parallel flows 710, 712 and 714 along the row of the electronics modules 602-606. The thermal device 700 is configured so that a flow 710 enters the thermal device 700 at the electronics module 704 and continues as flows 712 and 714 that are oriented in opposite directions to each other. The fluid continues past the electronics modules 702 and 706, respectively, which are at respective sides of the electronics module 704. The thermal device 700 can have pin fins extending from a surface of the baseplate 708 for some or all of the electronics modules 702-706. A spacing between adjacent ones of such pin fins can have a gradient. In some implementations, a gradient can be formed in the direction of flow for at least one of the flows 712-714. For example, the gradient includes a first gradient along the direction of the flow 712 and a second gradient along the direction of the flow 714. In other implementations, the gradient can also or instead be formed in a direction other than the direction(s) of flow.

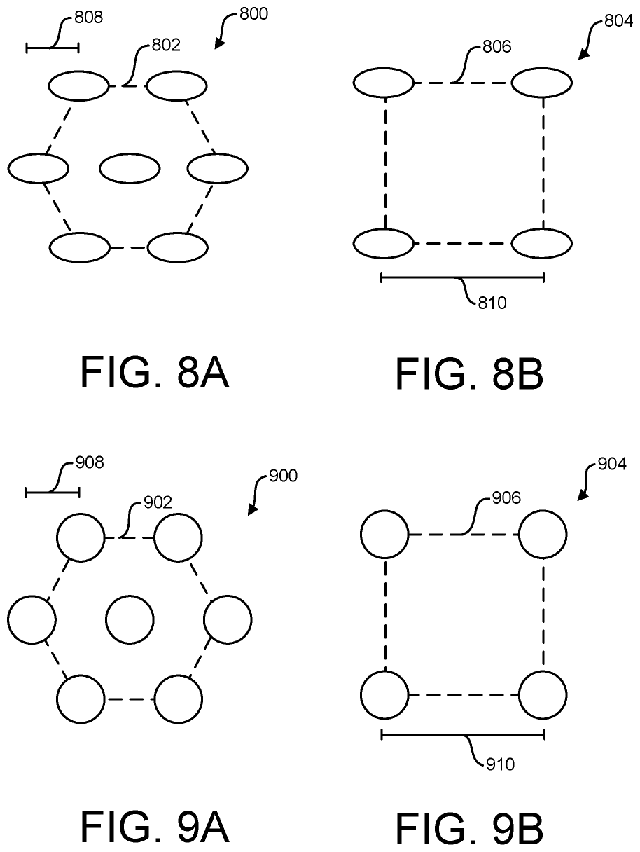

FIGS. 8A-8B show examples of pin fins 800 with an elliptical cross section in a hexagonal pattern 802 and pin fins 804 with an elliptical cross section in an offset pattern 806. The pin fins 800 and/or 804 can be used with one or more other examples described elsewhere herein. A spacing between adjacent ones of the pin fins 800 and/or 804 can have a gradient. For example, a spacing 808 defined between two of the pin fins 800 can vary along the hexagonal pattern 802. With reference briefly again to FIG. 2, the column 200 can include at least a first pin fin of the pin fins 800, and the column 202 can include at least second and third pin fins of the pin fins 800. The spacing 808 can then be defined as the distance between the first pin fin and the second and third pin fins. As another example, a spacing 810 defined between two of the pin fins 804 can vary along the offset pattern 806. The gradient can include any type of configuration/separation change that causes a change in pin fin density.

FIGS. 9A-9B show examples of pin fins 900 with a circular cross section in a hexagonal pattern 902 and pin fins 904 with a circular cross section in an offset pattern 906. The pin fins 900 and/or 904 can be used with one or more other examples described elsewhere herein. A spacing between adjacent ones of the pin fins 900 and/or 904 can have a gradient. For example, a spacing 908 defined between two of the pin fins 900 can vary along the hexagonal pattern 902. With reference briefly again to FIG. 2, the column 200 can include at least a first pin fin of the pin fins 900, and the column 202 can include at least second and third pin fins of the pin fins 900. The spacing 908 can then be defined as the distance between the first pin fin and the second and third pin fins. As another example, a spacing 910 defined between two of the pin fins 904 can vary along the offset pattern 906. The gradient can include any type of configuration/separation change that causes a change in pin fin density.

The terms “substantially” and “about” used throughout this Specification are used to describe and account for small fluctuations, such as due to variations in processing. For example, they can refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%. Also, when used herein, an indefinite article such as “a” or “an” means “at least one.”

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein.

A number of implementations have been described. Nevertheless, it will be understood that various modifications may be made without departing from the spirit and scope of the specification.

In addition, the logic flows depicted in the figures do not require the particular order shown, or sequential order, to achieve desirable results. In addition, other processes may be provided, or processes may be eliminated, from the described flows, and other components may be added to, or removed from, the described systems. Accordingly, other implementations are within the scope of the following claims.

While certain features of the described implementations have been illustrated as described herein, many modifications, substitutions, changes and equivalents will now occur to those skilled in the art. It is, therefore, to be understood that appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A thermal device for electronics, the thermal device comprising:
a baseplate configured for having the electronics mounted thereto;
a manifold defining a cavity closed by the baseplate, the cavity having an inlet and an outlet for a fluid; and
pin fins extending from a surface of the baseplate inside the cavity, the pin fins arranged in a pattern, wherein a spacing between adjacent ones of the pin fins has a gradient.

2. The thermal device of claim 1, wherein the pin fins are arranged in at least first and second regions on the baseplate, and wherein the gradient is formed by a first spacing between the pin fins in the first region and a second spacing between the pin fins in the second region.

3. The thermal device of claim 2, wherein the baseplate comprises multiple regions including at least the first and second regions and a third region, the multiple regions arranged in a row on the baseplate.

4. The thermal device of claim 3, wherein the gradient comprises that the spacing strictly decreases along the row in a flow direction of the fluid through the thermal device.

5. The thermal device of claim 1, wherein the pattern comprises a hexagonal pattern of the pin fins.

6. The thermal device of claim 1, wherein the pattern comprises an offset pattern of the pin fins.

7. The thermal device of claim 1, wherein the pattern comprises that the pin fins are arranged in columns that are perpendicular to a flow direction of the fluid through the thermal device.

8. The thermal device of claim 7, wherein the pin fins have a common separation from each other along each of the columns.

9. The thermal device of claim 7, wherein adjacent ones of the columns are offset from each other perpendicular to the flow direction of the fluid.

10. The thermal device of claim 9, wherein a first pin fins of the pin fins is located in a first column of the columns, wherein second and third pin fins of the pin fins are located in a second column of the columns, the second column adjacent to the first column, and wherein the spacing is defined as a distance between the first pin fin and the second and third pin fins.

11. The thermal device of claim 1, wherein the electronics comprises electronics modules arranged in a row on the baseplate.

12. The thermal device of claim 11, wherein the thermal device is configured so the fluid forms parallel flows that are perpendicular to the row, and wherein the pattern comprises that a respective gradient is formed for each of the parallel flows.

13. The thermal device of claim 12, wherein flow directions of the parallel flows are in a common direction across the row.

14. The thermal device of claim 12, wherein the thermal device is configured so the fluid forms a serial flow.

15. The thermal device of claim 14, wherein the thermal device is configured so the serial flow forms a serpentine shape that repeatedly crosses the row.

16. The thermal device of claim 14, wherein the pattern comprises that the gradient extends along the serial flow.

17. The thermal device of claim 11, wherein the thermal device is configured so the fluid enters the thermal device at a first electronics module of the electronics modules and continues in first and second directions that are opposite each other and continues past second and third electronics modules that are at respective sides of the first electronics module in the row.

18. The thermal device of claim 17, wherein the gradient comprises a first gradient along the first direction and a second gradient along the second direction.

19. The thermal device of claim 1, wherein the thermal device is configured for cooling the electronics, and wherein the fluid is a coolant.

20. The thermal device of claim 1, wherein the thermal device is configured for heating the electronics.

21. The thermal device of claim 1, wherein the gradient extends along a flow direction of the fluid.
